(19) United States
(12) Patent Application Publication
(10) Pub. No.: US 2009/0246553 A1
(43) Pub. Date: Oct. 1, 2009

(54) REFLECTIVE FILM AND METHOD FOR MANUFACTURING THE SAME

(75) Inventors: Po-Kai Chiu, Hsinchu City (TW); Wen-Hao Cho, Hsinchu City (TW); Hung-Ping Chen, Tainan Hsien (TW); Han-Chang Pan, Taichung City (TW); Chien-Nan Hsiao, Fongyuan City (TW)

Correspondence Address: VOLPE AND KOENIG, P.C., UNITED PLAZA, SUITE 1600, 30 SOUTH 17TH STREET, PHILADELPHIA, PA, 19103, US

(73) Assignee: NATIONAL APPLIED RESEARCH LABORATORIES, Taipei (TW)

(21) Appl. No.: 12/271,217

(22) Filed: Nov. 14, 2008

(30) Foreign Application Priority Data
Mar. 26, 2008 (TW) 97110885

(51) Int. Cl. B32B 15/04; B05D 1/36; C23C 14/24; C23C 14/34; B05D 3/02

(52) U.S. Cl. 428/656; 427/404; 427/250; 204/192.12; 427/383.1

(57) ABSTRACT

A reflective film is provided. The reflective film includes a substrate; a middle layer disposed on the substrate and mainly having a crystallized transition metal; and a metal layer disposed on the middle layer.

### FIELD OF THE INVENTION

The present invention relates to a reflective film and the method for manufacturing the same, and more particularly to a multi-layer reflective film and the method for manufacturing the same.

### BACKGROUND OF THE INVENTION

There are a lot of methods of forming a reflective film. These methods include physical and chemical methods, wherein the vacuum evaporating method has the advantage of fast manufacturing and convenient manufacturing for multi-layer films and therefore is still the main method of optical evaporation. The method of evaporation and sputtering is a technology that heats the target in the vacuum to reach a melting or evaporating point to evaporate the target, thereby depositing and coating a film on the surface of the substrate. Nowadays the materials of the target are mainly silver and aluminum. Although these metals possess a good reflective rate, the reflective film formed thereby has the problem of poor attachment to the substrate which often results in the crack film. It is known at present that adding a layer of chromium or aluminum oxide between the metal reflective layer and substrate helps the improvement of the attachment of the metal reflective layer. Besides, heating during or after the evaporation/sputtering process helps the film and substrate to form a better bounding to avoid pilling and increase adherence. However, this decreases the reflective rate.

In order to overcome the drawbacks in the prior art, an improved reflective film and the method for manufacturing the same are provided. The particular design in the present invention not only solves the problems described above, but also is easy to be implemented. Thus, the present invention has the utility for the industry.

### SUMMARY OF THE INVENTION

The reflective film and its manufacturing method of the present invention not only possess high reflection effect, but the adherence of the metal reflective layer also increases.

It is an aspect of the present invention to provide a reflective film. The reflective film comprises a substrate; a middle layer disposed on the substrate and mainly having a crystallized transition metal; and a metal layer disposed on the middle layer.

Preferably, the reflective film further comprises a protection layer, disposed on the metal layer to avoid an oxidation of the crystallized metal layer.

Preferably, the protection layer comprises at least one selected from a group consisting of a metal oxide, a silicon oxide, a metal nitride and a silicon nitride.

Preferably, the crystallized transition metal is chrome.

Preferably, the crystallized metal layer is made of at least one selected from a group consisting of In, Sn, Au, Pt, Zn, Ag, Cu, Ti, Pb, an alloy of Au and Be, an alloy of Au and Ge, Ni, an alloy of Pb and Sn and an alloy of Au and Zn.

It is another aspect of the present invention to provide a method of manufacturing a reflective film, comprising steps of (a) providing a substrate layer; (b) depositing a crystallized transition metal on the substrate layer to form a middle layer; and (c) depositing a metal layer on the middle layer.

Preferably, the method further comprises a step of crystallizing a transition metal to obtain the crystallized transition metal for performing the step (b).

Preferably, the method further comprises a step of forming a protection layer on the metal layer to avoid an oxidation of the metal layer.

Preferably, the protection layer comprises at least one selected from a group consisting of a metal oxide, a silicon oxide, a metal nitride and a silicon nitride.

Preferably, the method further comprises a step of forming a sticker layer between any two layers of the substrate layer, the middle layer and the metal layer.

Preferably, the evaporation is assisted by providing an ion source.

Preferably, at least one of the depositing steps (b) and (c) further comprises a step of heating the substrate layer.

Preferably, the crystallized transition metal is Chrome.

Preferably, the metal layer is made of at least one selected from a group consisting of In, Sn, Au, Pt, Zn, Ag, Cu, Ti, Pb, an alloy of Au and Be, an alloy of Au and Ge, Ni, an alloy of Pb and Sn.

The above objects and advantages of the present invention will become more readily apparent to those ordinarily skilled in the art after reviewing the following detailed descriptions and accompanying drawings, in which:

### BRIEF DESCRIPTION OF THE DRAWINGS

FIG. 1 is a schematic diagram showing the X-ray diffraction of the conventional reflective film,

FIG. 2 is a schematic diagram showing the adherence of the conventional reflective film;

FIG. 3 is a side view of the reflective film according to the first embodiment of the present invention;

FIG. 4 is a side view of the reflective film according to the second embodiment of the present invention;

FIG. 5 is a schematic diagram showing the manufacturing method of the reflective film according to the second embodiment of the present invention;

FIG. 6 is a schematic diagram showing the pre-cleaning process of the manufacturing method of the reflective film in the present invention;

FIG. 7 is a schematic diagram showing the X-ray diffraction of the reflective film according to the first embodiment of the present invention; and

FIG. 8 is a schematic diagram showing the test of the adherence of the reflective film according to the first embodiment of the present invention.

### DETAILED DESCRIPTION OF THE PREFERRED EMBODIMENT

The present invention will now be described more specifically with reference to the following embodiments. It is to be noted that the following descriptions of preferred embodiments of this invention are presented herein for the purposes of illustration and description only; it is not intended to be exhaustive or to be limited to the precise form disclosed.

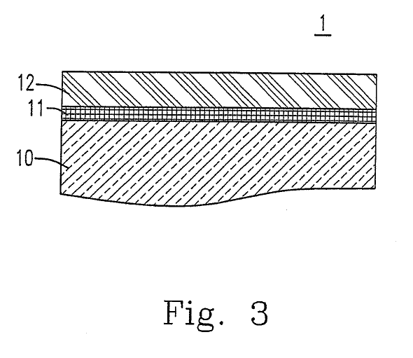

Please refer to FIG. 3. FIG. 3 is a side view of the reflective film according to the first embodiment of the present invention. The reflective film 1 of the present invention comprises a substrate 10, a crystallized chrome buffer film 11, and a silver reflective film 12. The material of the substrate 10 is not specifically limited; in the embodiments of the present invention, it is illustrated by some flexible substrates such as the cloth, fiber, paper, PVC sheet, macromolecule sheet, etc. The general metal material used to form the metal reflective film for the ultraviolet region is aluminum, for the visible light region is aluminum and silver (Ag), for the infrared region is gold (Au), silver and copper (Cu), and for other demand is indium(In), tin (Sn), platinum(Pt), zinc (Zn), silver (Ag), titanium (Ti), lead (Pb), alloy of Au and Be (AuBe), alloy of Au and Ge (AuGe), nickel (Ni), alloy of Pb and Sn (PbSn), or alloy of Au and zinc (AuZn), etc. The chrome buffer film 11 can significantly promote the adherence strength between the silver reflective film 12 and the substrate 10, and the crystallized chrome buffer film 11 especially has an even more significant effect. This purpose may also be achieved by replacing the chrome with other transition metals.

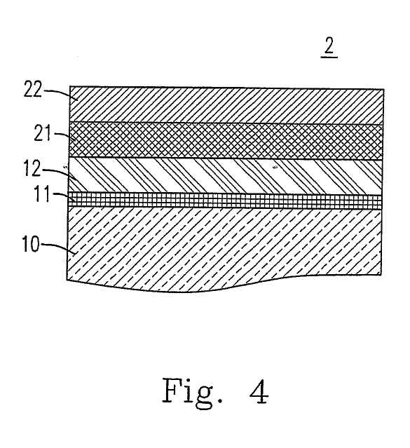

Please refer to FIG. 4. FIG. 4 is a side view of the reflective film according to the second embodiment of the present invention. The reflective film 2 of the second embodiment is the reflective film 12 of the first embodiment covered with a silicon dioxide protection film 21 and a titanium dioxide protection film 22. Because the metal materials such as aluminum, silver, copper and so on are easy to oxidize in the air and therefore the reflectivity is reduced. Hence, covering the protection film on the surface of the silver reflective film 12 can protect the silver reflective film 21 from the scratch and oxidation, thereby enhancing the strength and reflectivity of the whole reflective film 2. The material of the protection film can be a metal oxide, a silicon oxide, a metal nitrogen, or a silicon nitride, etc., wherein a silicon monoxide, a magnesium fluoride, a silicon dioxide, an aluminum oxide, and a titanium dioxide are often used. When the aluminum reflective film is used in the visible light region, it is often with a protection film made of a silicon monoxide or an aluminum oxide. And for the silver reflective film, it can be protected by the protection film made of the above materials, a uranium coating, or a lacquer painting.

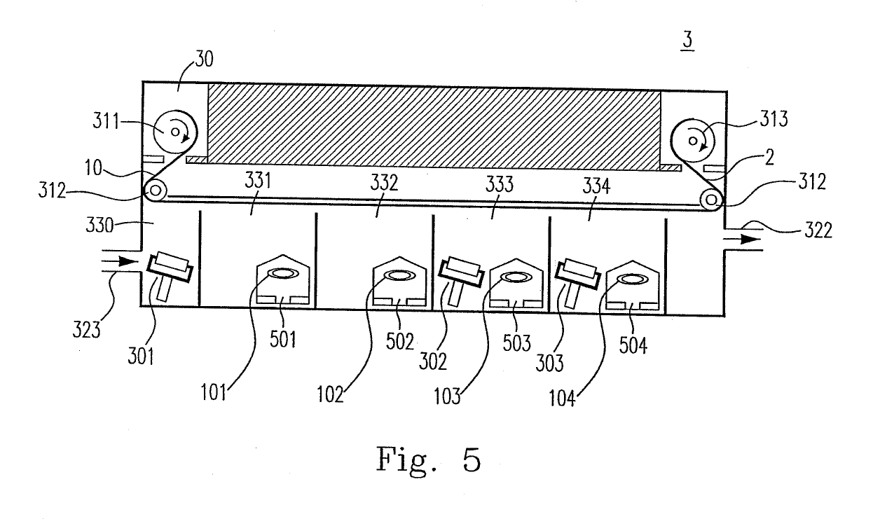

Please refer to FIG. 5. FIG. 5 is a schematic diagram showing the manufacturing method of the reflective film according to the second embodiment of the present invention. This embodiment is illustrated by an evaporation method to deposit a multi-layer structure of chromium, silver, titanium oxide, and silicon dioxide on a plastic substrate. The substrate 10 of this embodiment is automatically and continuously processed to form the reflective film 2 thereon by the manufacturing equipment 3 of FIG. 5. The manufacturing method comprises the following steps.

The manufacturing equipment 3 is prepared for automatically and continuously producing the reflective film 2.

The to-be-processed substrate 10 is placed. The substrate 10 is set up on a substrate-loading-wheel 311 inside the vacuum chamber 30 by coiling.

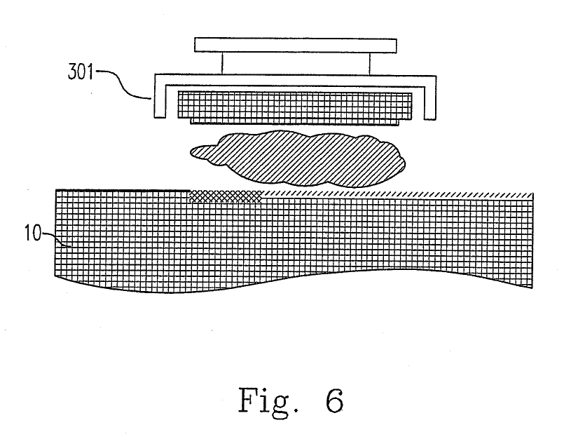

Please refer to FIG. 5. The substrate 10 is put on the substrate-loading-wheel 311, and then the vacuum pump is actuated to extract the air via the vacuum air-extracting pipe 322. Next, when the vacuum of the vacuum chamber 30 is below the background pressure value of 8×10⁻⁶, the oxygen is introduced via the oxygen-inlet-pipe 323 until the work pressure of 2.4×10⁻⁴ and then the pre-cleaning process is ready to be performed. The proceeding speed of the substrate 10 is adjusted before the substrate 10 enters the pre-cleaning area 330, and the chromium dosage 101 and silver dosage 102 are heated up and melted at the same time. After the substrate 10 enters the pre-cleaning area 330, the ion source 301 is actuated to perform the pre-cleaning process for the substrate (as shown in FIG. 6). The pre-cleaning process promotes the adherence strength of the surface of the substrate 10 and thus benefits the following evaporation process.

Please refer to FIGS. 4 and 5. After undergoing the pre-cleaning process, the substrate 10 is sent to the first evaporating area 331 via the lead wheel 312. In the first evaporating area 331, the chromium dosage 101 is heated up by the first heating source 501 to generate chromium to form membrane particles to deposit on the surface of the substrate 10, so that a chromium film with the thickness of 0-40% of the spectrum transmittance is formed at the deposition rate of 20 Å/s. After the first chromium film is deposited, the substrate 10 is sent to the second evaporating area 332. In the second evaporating area 332, the chromium dosage 102 is heated up by the second heating source 502 to generate silver to form membrane particles to deposit on the surface of the substrate 10, so that a silver film with the thickness of 50˜300 nm is formed. After the second silver film is deposited, the substrate 10 is sent to the third evaporating area 333. In the third evaporating area 333, the SiO₂ drug 103 is heated up by the third heating source 503. Firstly, a SiO₂ film with the thickness of 30-50 nm is deposited without introducing the working gas. Then, the oxygen is introduced until 2.4×10⁻⁴ Torr, and the SiO₂ film 21 with the thickness of 68 nm is deposited with the assistance of the first ion source 302. After the third layer of SiO₂ film is deposited, the substrate 10 is sent to the fourth evaporating area 334. In the fourth evaporating area 334, the TiO₂ drug 104 is heated up by the fourth heating source 504, and a TiO₂ film with the thickness of 47 nm is deposited with the assistance of the second ion source 303. After the four layers of film are deposited, the manufacturing of the reflective film 2 is completed. Finally, the completed reflective films 1 and 2 are collected by the substrate-collecting-wheel 313. If two surfaces of the substrate 10 are to be coated with films, the substrate 10 can be coiled from the other side, and then the above-mentioned evaporation process is performed for the substrate 10 to obtain a double-faced reflective film.

Specifically speaking, the monitoring system used in this embodiment during the evaporating process includes an optical monitoring system and a quartz monitor system that is often used in the industry, for monitoring the evaporating rate and the film thickness. And in this embodiment, the crucible used is made of chromium and silver with a diameter of 40 mm, and the working temperature is 25° C. The evaporating parameters of this embodiment are listed in Table 1.

TABLE 1

| | | Iron Source | | Film | |
|---|---|---|---|---|---|
| | Iron | Accelerating | Working | Deposition | |
| | Source | Voltage | Temperature | Rate | Vacuity |
| | (W) | (V) | (° C.) | (Å/s) | (Torr) |
| Silver | None | None | 25 | 80 | 4 × 10⁻⁴ |
| Film | | | | | |
| Chromium | None | None | 25 | 20 | 2 × 10⁻⁴ |
| Film | | | | | |
| TiO₂ Film | 300 | 300 | 25 | 2 | 2.4 × 10⁻⁴ |
| SiO₂ Film | 300 | 300 | 25 | 10 | 2.4 × 10⁻⁴ |

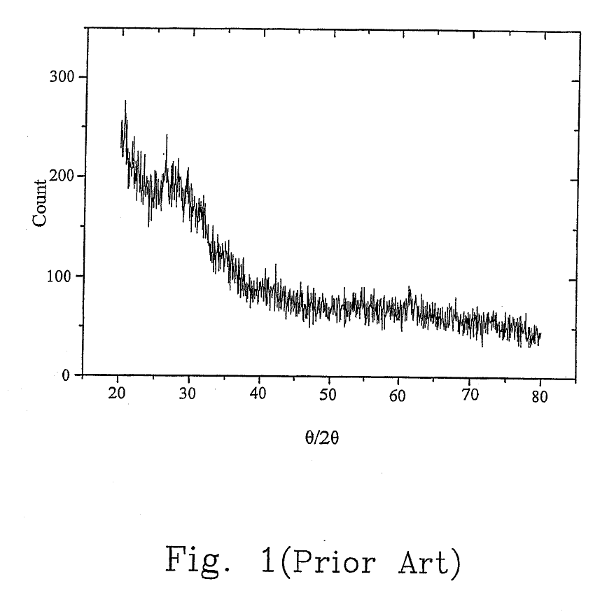

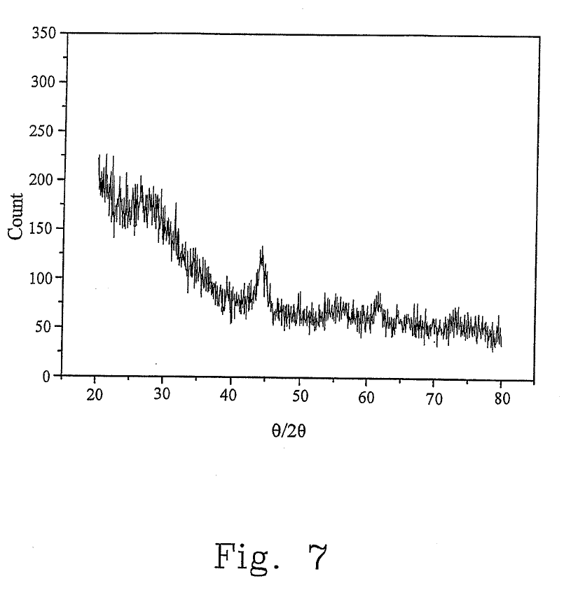

Please refer to FIGS. 1 and 7. FIG. 1 is a schematic diagram showing the X-ray diffraction of the conventional reflective film, and FIG. 7 is a schematic diagram showing the X-ray diffraction of the reflective film according to the first embodiment of the present invention. The reflective film manufactured by the conventional method includes the substrate, the chromium film and the silver chromium, wherein the chromium film presents a non-crystalline status (as shown in FIG. 1). However, the chromium film of the reflective film of the first embodiment in the present invention obviously possesses the crystal characteristic (as shown in FIG. 7). The above manufacturing method utilizes the accelerated deposition rate to let the chromium film possess the crystal characteristic. Besides, heating during or after the evaporation process also benefits the generation of the crystal of the chromium film. However, the reflectivity of the reflective film will be reduced by this method. Besides, the assistance of the iron source during the evaporation process also benefits the generation of the crystal. However, this method requires an extra iron source equipment, which results in a higher cost.

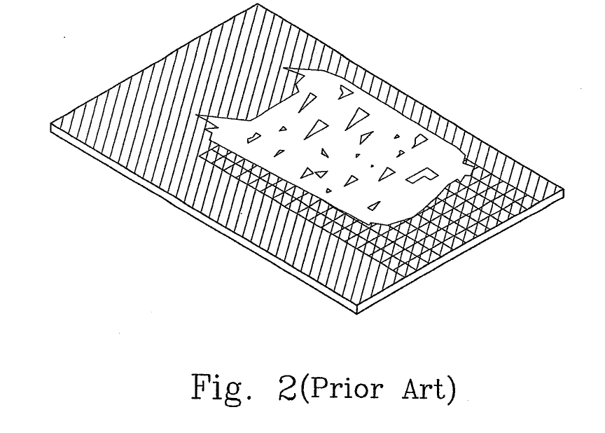

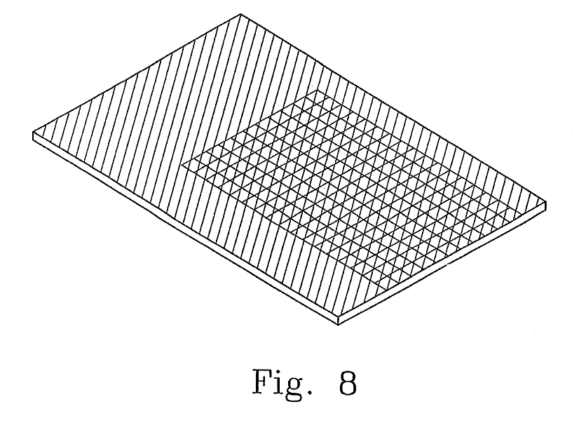

According to ASTM D3359 test method, the test of the adherence of the above reflective films shows that the adherence of the conventional reflective film is rated B degree. The judge criterion is that a lot of peeling near the edge of the notch occurs, or partial or entire peeling of some grids occurs, wherein the peeling area is greater than 65% of the grids area (as shown in FIG. 2). Nevertheless, the adherence of the reflective film of the present invention is rated 5 B degree, wherein the judge criteria are that the edge of the notch is completely smooth and no peeling occurs around the edge of the grids (as shown in FIG. 8). Based on the above, the reflective film manufactured by the present invention is firmer, and the crystallized buffer film makes the adherence of the reflective film greatly improved from 0 B to 5 B. The present invention improves the durability of the silver reflective film and conquers the environmental limitation. Moreover, the present invention further benefits the promotion of the manufacturing ability of the reflective mirror device in the industry.

The method of the present invention can greatly reduce the process temperature (reduced down to less than 100° C.), so that the applications of the reflective film of the present invention are wider, especially suitable for the flexible substrate which can not endure high temperature. Besides, the present invention can significantly reduce the process time and enhance the production efficiency by reducing the heating and cooling time, so that it can satisfy the needs of the continuous production for the large-scale product and the mass production. If the present film-coating manufacturers want to utilize the method of the present invention to manufacture the reflective film, they do not need to purchase extra expansive equipments; they can directly manufacture the reflective film of the present invention which is more durable by the equipment on hand, which needs no extra costs.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all such modifications and similar structures.

What is claimed is:

1. A reflective film, comprising:
a substrate;
a middle layer disposed on the substrate and mainly having a crystallized transition metal; and
a metal layer disposed on the middle layer.

2. A reflective film as claimed in claim 1, being manufacturing by a method of evaporation and a sputtering.

3. A reflective film as claimed in claim 1, further comprising:
a protection layer, disposed on the metal layer to avoid an oxidation of the crystallized metal layer.

4. A reflective film as claimed in claim 3, wherein the protection layer comprises at least one selected from a group consisting of a metal oxide, a silicon oxide, a metal nitride and a silicon nitride.

5. A reflective film as claimed in claim 1, wherein the crystallized transition metal is chrome.

6. A reflective film as claimed in claim 1, wherein the crystallized metal layer is made of at least one selected from a group consisting of In, Sn, Au, Pt, Zn, Ag, Cu, Ti, Pb, an alloy of Au and Be, an alloy of Au and Ge, Ni, an alloy of Pb and Sn and an alloy of Au and Zn.

7. A method of manufacturing a reflective film, comprising steps of:
(a) providing a substrate layer;
(b) depositing a crystallized transition metal on the substrate layer to form a middle layer; and
(c) depositing a metal layer on the middle layer.

8. A method of manufacturing a reflective film as claimed in claim 7, further comprising a step of:
crystallizing a transition metal to obtain the crystallized transition metal for performing the step (b).

9. A method of manufacturing a reflective film as claimed in claim 7, wherein each of the deposition steps (b) and (c) is performed by one of an evaporation and a sputtering method.

10. A method of manufacturing a reflective film as claimed in claim 9, wherein the evaporation is assisted by providing an ion source.

11. A method of manufacturing a reflective film as claimed in claim 7, further comprising a step of:
forming a protection layer on the metal layer to avoid an oxidation of the metal layer.

12. A method of manufacturing a reflective film as claimed in claim 11, wherein the protection layer comprises at least one selected from a group consisting of a metal oxide, a silicon oxide, a metal nitride and a silicon nitride.

13. A method of manufacturing a reflective film as claimed in claim 7, further comprising a step of:
forming a sticker layer between any two layers of the substrate layer, the middle layer and the metal layer.

14. A method of manufacturing a reflective film as claimed in claim 7, wherein at least one of the depositing steps (b) and (c) further comprises a step of heating the substrate layer.

15. A method of manufacturing a reflective film as claimed in claim 7, wherein the crystallized transition metal is Chrome.

16. A method of manufacturing a reflective film as claimed in claim 6, wherein the metal layer is made of at least one selected from a group consisting of In, Sn, Au, Pt, Zn, Ag, Cu, Ti, Pb, an alloy of Au and Be, an alloy of Au and Ge, Ni, an alloy of Pb and Sn.

17. A method of manufacturing a reflective film, comprising steps of:
(a) providing a substrate;
(b) depositing a transition metal on the substrate;
(c) crystallizing the transition metal for forming a middle layer; and
(d) depositing a metal layer on the middle layer.

18. A method of manufacturing a reflective film as claimed in claim 17, wherein each of the deposition steps (b) and (c) is performed by one of an evaporation and a sputtering method.

19. A method of manufacturing a reflective film as claimed in claim 17, further comprising a step of:
forming a protection layer on the metal layer to avoid an oxidation of the metal layer.

20. A method of manufacturing a reflective film as claimed in claim 17, wherein the crystallized transition metal is Chrome.
